(19) United States
(12) Patent Application Publication
(10) Pub. No.: US 2016/0268146 A1
(43) Pub. Date: Sep. 15, 2016

(54) SUBSTRATE PROCESSING APPARATUS AND SUBSTRATE PROCESSING METHOD

(71) Applicant: SCREEN Holdings Co., Ltd., Kyoto (JP)

(72) Inventor: Kenji KOBAYASHI, Kyoto (JP)

(21) Appl. No.: 15/061,095

(22) Filed: Mar. 4, 2016

(30) Foreign Application Priority Data
Mar. 10, 2015 (JP) 2015-047569

(51) Int. Cl. H01L 21/67; H01L 21/02; H01L 21/306

(52) U.S. Cl. CPC H01L 21/6708; H01L 21/67051; H01L 21/30604; H01L 21/02041

(57) ABSTRACT

A substrate processing apparatus includes a processing liquid nozzle that includes a nozzle pipe within which a processing liquid flow path is defined and a discharge port to which the processing liquid flow path is opened, a processing liquid holding unit that holds the processing liquid while maintaining the processing liquid at a predetermined high temperature higher than a room temperature, a processing liquid pipe that is connected to the processing liquid holding unit and the processing liquid nozzle and that guides the processing liquid held by the processing liquid holding unit to the processing liquid nozzle and an induction heating unit that heats, by induction heating, a heating target part which is provided in at least a part of a processing liquid distribution pipe including the processing liquid pipe and the nozzle pipe and which includes a magnetic inductive member material and/or a carbon material.

### BACKGROUND OF THE INVENTION

1. Field of the Invention

The present invention relates to a substrate processing apparatus and a substrate processing method. Examples of the substrate to be processed include semiconductor wafers, substrates for liquid crystal display devices, substrates for plasma displays, substrates for FEDs (Field Emission Displays), substrates for optical discs, substrates for magnetic discs, substrates for optical magnetic discs, substrates for photomasks, ceramic substrates and substrates for solar cells.

2. Description of Related Art

In the manufacturing process of semiconductor devices and liquid crystal display devices, processing using a processing liquid is performed on substrates such as semiconductor wafers or glass substrates for liquid crystal display devices. For example, a single substrate processing type substrate processing apparatus that processes substrates one by one includes a spin chuck that rotates the substrate while holding the substrate horizontally and a processing liquid nozzle that supplies the processing liquid to the front surface of the substrate held by the spin chuck. In some apparatuses, a chemical liquid that is adjusted to have a predetermined high temperature may be supplied to the processing liquid nozzle.

Japanese Patent Application Publication No. 2013-172079 discloses a substrate processing apparatus that includes a tank for storing a chemical liquid and a processing liquid supply pipe which is extended from the tank. In the processing liquid supply pipe, a pump, a temperature adjustment unit and a processing liquid valve are interposed in this order from an upstream side. The substrate processing apparatus further includes a return path for feeding back the chemical liquid passed along the processing liquid supply pipe to the tank. One end of a return pipe is connected between the temperature adjustment unit and the processing liquid valve, and the other end of the return pipe is connected to the tank.

When the chemical liquid is not supplied to the front surface of the substrate, the processing liquid valve is closed, and a return valve is opened, and thus the chemical liquid of high temperature passed along the processing liquid supply pipe is passed from a branch portion through the return path and is fed back to the tank. In other words, when the substrate is not processed, the chemical liquid of high temperature is circulated in a circulation path formed with the tank, the processing liquid supply pipe and the return path.

On the other hand, when the processing using the chemical liquid of high temperature is performed on the front surface of the substrate, the return valve is closed, and the processing liquid valve is opened, and thus the chemical liquid of high temperature circulated in the circulation path is supplied via the processing liquid supply pipe to the processing liquid nozzle.

However, in the configuration disclosed in Japanese Patent Application Publication No. 2013-172079, while the processing liquid valve is closed, the chemical liquid is not present in the processing liquid supply pipe and the nozzle pipe of the processing liquid nozzle, and the processing liquid supply pipe and the nozzle pipe of the processing liquid nozzle are maintained at room temperature. Hence, the processing liquid valve is opened, and thus in the process in which the chemical liquid of high temperature fed from the circulation path to a downstream side portion (referred to as a “downstream side portion of the processing liquid supply pipe”) with respect to the branch position of the processing liquid supply pipe flows through the downstream side portion of the processing liquid supply pipe and the nozzle pipe of the processing liquid nozzle, the chemical liquid is cooled by heat exchange with the pipe wall of the downstream side portion of the processing liquid supply pipe and the pipe wall of the nozzle pipe, with the result that the chemical liquid whose temperature is lowered may be supplied to the substrate.

### SUMMARY OF THE INVENTION

In order to prevent the processing liquid (chemical liquid) whose temperature is lowered from being used for processing on the substrate, pre-dispensing in which the processing liquid valve is opened in the state where the processing liquid nozzle is faced toward a space where the substrate is not present is performed before the supply of the processing liquid to the substrate to be processed. In the pre-dispensing, the processing liquid of high temperature is passed through the downstream side portion of the processing liquid supply pipe and the nozzle pipe of the processing liquid nozzle, and consequently, the pipe wall of the downstream side portion and the pipe wall of the nozzle pipe are warmed by the processing liquid of high temperature, and thus these pipe walls are increased in temperature to the same degree of the temperature of the processing liquid. Thereafter, there is no possibility that the processing liquid is cooled by the pipe wall of the downstream side portion of the processing liquid supply pipe and the pipe wall of the nozzle pipe. In this way, it is possible to discharge, from the processing liquid nozzle, the processing liquid that is adjusted to have a desired high temperature.

However, since the processing liquid discharged from the processing liquid nozzle by the pre-dispensing is changed in chemical properties as a result of being increased and then lowered in temperature, the processing liquid cannot be reused for processing on the substrate and thus needs to be discarded. Hence, disadvantageously, when it takes a long time to perform the pre-dispensing, the amount of processing liquid discharged from the processing liquid nozzle in the pre-dispensing is increased, and thus the amount of processing liquid consumed is increased. Moreover, when it takes a long time to perform the pre-dispensing, the throughput of the processing is disadvantageously lowered.

In other words, even when the pre-dispensing of the processing liquid is eliminated or the pre-dispensing is performed, it is required to reduce the time necessary for the pre-dispensing and/or to reduce the amount of processing liquid consumed for the pre-dispensing of the processing liquid.

Hence, an object of the present invention is to provide a substrate processing apparatus and a substrate processing method that can discharge, from a processing liquid nozzle, a processing liquid which is adjusted to have a desired high temperature while eliminating pre-dispensing or reducing a time necessary for pre-dispensing and/or reducing the amount of processing liquid consumed for pre-dispensing.

According to this invention, there is provided a substrate processing apparatus including a substrate holding unit that holds a substrate, a processing liquid nozzle that includes a nozzle pipe within which a processing liquid flow path for passing a processing liquid is defined and a discharge port to which the processing liquid flow path is opened, a processing liquid holding unit that holds the processing liquid while maintaining the processing liquid at a predetermined high temperature higher than a room temperature, a processing liquid pipe that is connected to the processing liquid holding unit and the processing liquid nozzle and that guides the processing liquid held by the processing liquid holding unit to the processing liquid nozzle, and an induction heating unit that heats, by induction heating, a heating target part which is provided in at least a part of a processing liquid distribution pipe including the processing liquid pipe and the nozzle pipe and which includes a magnetic inductive member material and/or a carbon material.

According to this configuration, the heating target part is provided in at least a part of the processing liquid distribution pipe, and the heating target part contains the magnetic inductive member material and/or the carbon material. The heating target part is heated with the induction heating unit by induction heating, and thus it is possible to increase the temperature of the heating target part. Hence, in the state where the processing liquid is not discharged from the processing liquid nozzle, at least apart of the processing liquid distribution pipe is heated, and thus the part can be maintained at a temperature that is substantially equal to the temperature of the processing liquid supplied from the processing liquid holding unit.

In this case, without a large amount of processing liquid being discharged from the processing liquid nozzle, only by discharging a small amount of processing liquid from the processing liquid nozzle, the entire processing liquid distribution pipe can be increased to the temperature that is substantially equal to the temperature of the chemical liquid supplied from the processing liquid holding unit. Hence it is possible to eliminate the pre-dispensing. Even when the pre-dispensing is performed, it is possible to reduce the time necessary for the pre-dispensing, and it is also possible to reduce the amount of processing liquid consumed for the pre-dispensing.

In this way, it is possible to discharge, from the discharge port of the processing liquid nozzle, the processing liquid which is adjusted to have a desired high temperature while eliminating the pre-dispensing or reducing the time necessary for the pre-dispensing and/or reducing the amount of processing liquid consumed for the pre-dispensing.

In a preferred embodiment of this invention, the heating target part includes a first heating target part which is provided in at least a part of the nozzle pipe of the processing liquid nozzle.

According to this configuration, the first heating target part containing the magnetic inductive member material and/or the carbon material is provided in at least a part of the nozzle pipe. The first heating target part is heated with the induction heating unit by induction heating, and thus it is possible to increase the temperature of the first heating target part. Hence, in the state where the processing liquid is not discharged from the processing liquid nozzle, at least a part of the nozzle pipe is heated, and thus the part can be maintained at the temperature that is substantially equal to the temperature of the processing liquid supplied from the processing liquid holding unit.

In this case, without a large amount of processing liquid being discharged from the processing liquid nozzle, only by discharging a small amount of processing liquid from the processing liquid nozzle, the entire processing liquid distribution pipe can be increased to the temperature that is substantially equal to the temperature of the chemical liquid supplied from the processing liquid holding unit. Hence it is possible to eliminate the pre-dispensing. Even when the pre-dispensing is performed, it is possible to reduce the time necessary for the pre-dispensing, and it is also possible to reduce the amount of processing liquid consumed for the pre-dispensing.

The processing liquid nozzle is provided such that the processing liquid nozzle can be moved between a processing position where the processing liquid is supplied to the substrate held by the substrate holding unit and a retraction position where the processing liquid nozzle is retracted from the substrate holding unit, and the induction heating unit may heat the first heating target part of the processing liquid nozzle which is located in the retraction position.

According to this configuration, the first heating target part of the processing liquid nozzle located in the retraction position is heated by the induction heating unit. For a long period of time in the period during which the processing liquid is not supplied to the substrate, the processing liquid nozzle is arranged in the retraction position. By effectively utilizing the period during which the processing liquid is not supplied to the substrate, the nozzle pipe can be warmed.

In the retraction position where the normal pre-dispensing of the processing liquid is performed, the induction heating unit heats the nozzle pipe. Thus, it is possible to warm the first heating target part of the nozzle pipe of the processing liquid nozzle until immediately before the pre-dispensing is performed.

The substrate processing apparatus may further include a chamber that accommodates the substrate holding unit and the processing liquid nozzle, where the chamber accommodates a plurality of the processing liquid nozzles, and each of the processing liquid nozzles includes the first heating target part. In this case, the induction heating unit may heat each of the first heating target parts.

According to this configuration, when a plurality of processing liquid nozzles are provided, it is possible to efficiently heat the first heating target part of the nozzle pipes.

The heating target part may include a second heating target part that is provided in at least a part of the processing liquid pipe.

According to this configuration, the second heating target part containing the magnetic inductive member material and/or the carbon material is provided in at least a part of the processing liquid supply pipe. The second heating target part is heated with the induction heating unit by induction heating, and thus it is possible to increase the temperature of at least a part of the processing liquid supply pipe. Hence, in the state where the processing liquid is not discharged from the processing liquid nozzle, at least a part of the processing liquid supply pipe is heated, and thus the part can be maintained at the temperature that is substantially equal to the temperature of the processing liquid supplied from the processing liquid.

The heating target part may include a third heating target part that is provided in at least a part of a valve body of a valve interposed in the processing liquid pipe.

According to this configuration, the third heating target part containing the magnetic inductive member material and/or the carbon material is provided in at least a part of the valve body of the valve. The third heating target part is heated with the induction heating unit by induction heating, and thus it is possible to increase the temperature of at least a part of the valve body of the valve. Hence, in the state where the processing liquid is not discharged from the processing liquid nozzle, at least a part of the valve body is heated, and thus the part can be maintained at the temperature that is substantially equal to the temperature of the processing liquid discharged from the processing liquid.

The processing liquid distribution pipe may have a multilayer structure that includes a first layer which contains the magnetic inductive member material and/or the carbon material and a second layer which surrounds the circumference of the first layer and which protects the first layer.

According to this configuration, since the second layer protects the first layer containing the magnetic inductive member material and/or the carbon material, it is possible to increase the life of the first layer. In this way, the heating of the heating target part by induction heating can be performed over a long period of time.

The magnetic inductive member material may include SUS. According to this configuration, since the heating target part includes SUS, the heating target part can be satisfactorily increased in temperature by the induction heating from the induction heating unit.

The induction heating unit may include an inductive coil and a power supply unit that supplies high-frequency power to the inductive coil. According to this configuration, it is possible to realize the induction heating unit with a simple configuration including the inductive coil and the current supply unit.

In this case, the heating target part may include the first heating target part provided in at least a part of the nozzle pipe, the processing liquid nozzle may be provided such that the processing liquid nozzle can be moved between a processing position where the processing liquid is supplied to the substrate held by the substrate holding unit and a retraction position where the processing liquid nozzle is retracted from the substrate holding unit, and the induction heating coil may be provided such that the induction heating coil can heat the first heating target part of the processing liquid nozzle which is located in the retraction position.

According to this configuration, the induction heating unit can be provided in a member other than the processing liquid nozzle arranged in the retraction position. In a case where the processing liquid nozzle can be moved, when the inductive coil is arranged within the processing liquid nozzle, it can be considered that its structure becomes complicated due to the wiring for the induction heating. By contrast, since the inductive coil is provided in another member arranged in the retraction position, it is possible to prevent the complicated wiring from being performed for the provision of the inductive coil.

In the retraction position, a pot may be provided that receives the processing liquid discharged from the processing liquid nozzle. In this case, the inductive coil may be arranged on a wall of the pot.

According to this configuration, the pot is provided as the other member, and thus it is possible to easily realize the arrangement of the inductive coil in the other member arranged in the retraction position.

There is provided a substrate processing method of supplying a processing liquid having a predetermined high temperature higher than a room temperature to a processing liquid nozzle that includes a nozzle pipe within which a processing liquid flow path for passing the processing liquid is defined and a discharge port to which the processing liquid flow path is opened via a processing liquid pipe so as to process the substrate with the processing liquid discharged from the processing liquid nozzle, the substrate processing method including a heating step of heating a heating target part provided in at least a part of a processing liquid distribution pipe including the processing liquid pipe and the nozzle pipe in a state where the processing liquid is not present within the heating target part so as to maintain a temperature of the heating target part at a high temperature which is higher than the room temperature but lower than a boiling point of the processing liquid.

According to this method, the heating target part is provided in at least a part of the processing liquid distribution pipe, and the heating target part is maintained by heating at the high temperature which is higher than the room temperature but lower than the boiling point of the processing liquid. Hence, in the state where the processing liquid is not discharged from the processing liquid nozzle, at least a part of the processing liquid distribution pipe is heated, and thus the part can be maintained at the temperature that is substantially equal to the predetermined high temperature.

In this case, without a large amount of processing liquid being discharged from the processing liquid nozzle, only by discharging a small amount of processing liquid from the processing liquid nozzle, the entire processing liquid distribution pipe can be increased to the temperature that is substantially equal to the temperature of the chemical liquid supplied from the processing liquid holding unit. Hence it is possible to eliminate the pre-dispensing. Even when the pre-dispensing is performed, it is possible to reduce the time necessary for the pre-dispensing, and it is also possible to reduce the amount of processing liquid consumed for the pre-dispensing.

In this way, it is possible to discharge, from the discharge port of the processing liquid nozzle, the processing liquid which is adjusted to have a desired high temperature while eliminating the pre-dispensing or reducing the time necessary for the pre-dispensing and/or reducing the amount of processing liquid consumed for the pre-dispensing.

In the preferred embodiment of this invention, the heating target part may contain a magnetic inductive member material and/or a carbon material, and the heating step may include an induction heating step of heating the heating target part by induction heating.

According to this method, the heating target part contains the magnetic inductive member material and/or the carbon material. The heating target part is heated with the induction heating unit by induction heating, and thus it is possible to increase the temperature of the heating target part. Hence, in the state where the processing liquid is not discharged from the processing liquid nozzle, at least a part of the processing liquid distribution pipe is heated, and thus the part can be maintained at the temperature that is substantially equal to the predetermined high temperature.

The method may further include a nozzle movement step of moving the processing liquid nozzle between a processing position where the discharge port is opposite to a main surface of the substrate and a retraction position where the discharge port is retracted from the main surface of the substrate. In the heating step, while the processing liquid nozzle is located in the retraction position, the heating target part may be heated.

According to this method, in the period during which the processing liquid nozzle is located in the retraction position, the heating target part can be heated. In this way, it is possible to warm at least a part of the processing liquid distribution pipe by effectively utilizing the period during which the processing liquid is not supplied to the substrate.

The heating step may include a first heating step of heating a first heating target part provided in at least a part of the nozzle pipe.

According to this method, the first heating target part is provided in at least a part of the nozzle pipe. The first heating target part is heated, and thus it is possible to increase the temperature of the first heating target part. Hence, in the state where the processing liquid is not discharged from the processing liquid nozzle, at least a part of the nozzle pipe is heated, and thus the part can be maintained at the temperature that is substantially equal to the predetermined high temperature.

In this case, without a large amount of processing liquid being discharged from the processing liquid nozzle, only by discharging a small amount of processing liquid from the processing liquid nozzle, the temperature of the entire processing liquid distribution pipe can be increased to the temperature that is substantially equal to the temperature of the chemical liquid supplied from the processing liquid holding unit. Hence it is possible to eliminate the pre-dispensing. Even when the pre-dispensing is performed, it is possible to reduce the time necessary for the pre-dispensing, and it is also possible to reduce the amount of processing liquid consumed for the pre-dispensing.

The objects, the features and the effects in the present invention described above or still other objects, features and effects will be more apparent from the following description of preferred embodiments with reference to the accompanying drawings.

### BRIEF DESCRIPTION OF THE DRAWINGS

FIG. 1 is a diagram of a substrate processing apparatus according to a first preferred embodiment of the present invention as viewed from a horizontal direction.

FIG. 2 is a schematic plan view showing the interior of a processing unit included in the substrate processing apparatus.

FIG. 3 is a cross-sectional view mainly showing the configuration of a chemical liquid nozzle.

FIG. 4 is a diagram taken along cross-sectional line IV-IV of FIG. 3.

FIG. 5 is a cross-sectional view showing a schematic configuration of a standby pot.

FIG. 6 is a flowchart for illustrating a processing example of processing performed by the substrate processing apparatus.

FIG. 7 is a time chart for illustrating the details of control performed by a control device in the processing example.

FIG. 8 is a diagram when a substrate processing apparatus according to a second preferred embodiment of the present invention is seen in the horizontal direction.

FIG. 9 is a schematic plan view showing the interior of a chamber included in the substrate processing apparatus.

FIG. 10 is a cross-sectional view showing a state where a chemical liquid nozzle according to a third preferred embodiment of the present invention is in a retraction position.

FIG. 11 is a cross-sectional view mainly showing the configuration of the vicinity of a first chemical liquid pipe according to a fourth preferred embodiment of the present invention.

FIG. 12 is a diagram taken along cross-sectional line XII-XII of FIG. 11.

FIG. 13 is a schematic cross-sectional view showing the configuration of a chemical liquid valve according to a fifth preferred embodiment of the present invention.

FIG. 14 is an enlarged cross-sectional view showing a part of the configuration shown in FIG. 13.

FIG. 15 is a diagram showing the configuration of a pipe according to a variation.

### DETAILED DESCRIPTION OF PREFERRED EMBODIMENTS

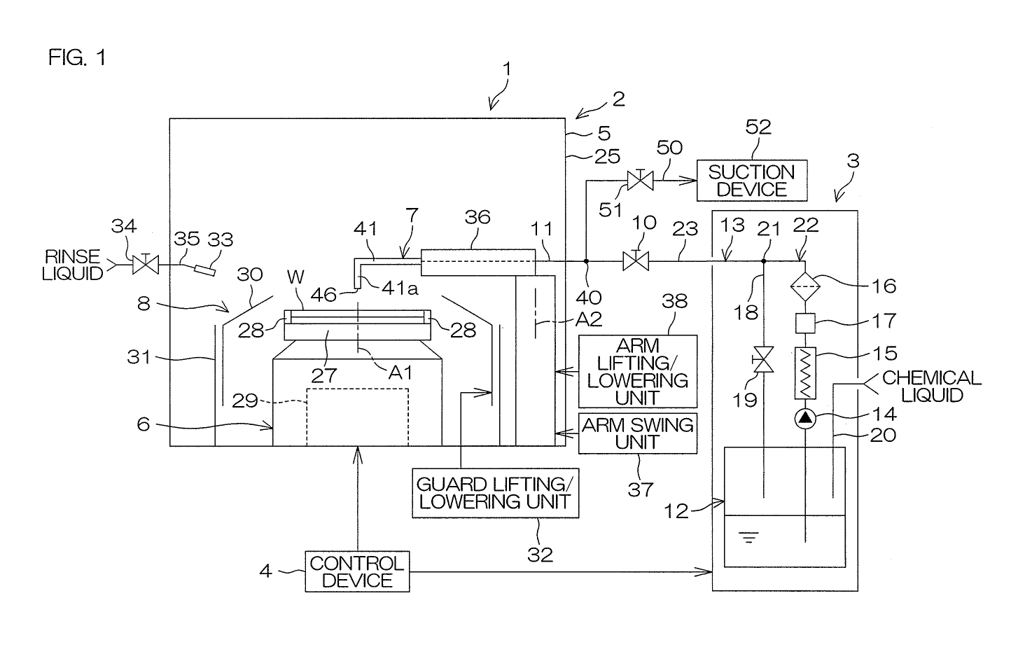

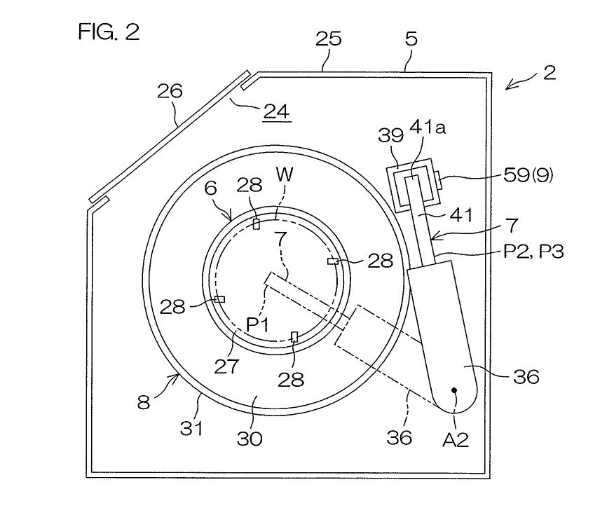

FIG. 1 is a diagram of a substrate processing apparatus 1 according to a first preferred embodiment of the present invention as viewed from a horizontal direction. FIG. 2 is a schematic plan view showing the interior of a processing unit 2 included in the substrate processing apparatus 1. The substrate processing apparatus 1 is a single substrate processing type apparatus that processes, as an example of a substrate W, semiconductor wafers one by one. The substrate processing apparatus 1 includes the processing unit 2 that processes the substrate W, a chemical liquid supply unit 3 that supplies, as an example of a processing liquid, a chemical liquid, to the processing unit 2 and a control device 4 that controls devices included in the substrate processing apparatus 1 and the opening and closing of a valve. The processing unit 2 and the chemical liquid supply unit 3 may be parts of a common unit or units independent of each other (units that can be moved independently of each other).

Although FIG. 1 shows, as an example, a case where the processing unit 2 is a single substrate processing type unit that processes the substrates W one by one, the processing unit 2 may be a batch type unit that processes a plurality of substrates W at a time. Although FIG. 1 shows only one chemical liquid supply unit 3, when a plurality of types of chemicals are provided, the chemical liquid supply units 3 that correspond in number to the types of chemicals may be provided.

The processing unit 2 includes a box-shaped chamber 5 that has an internal space, a spin chuck (substrate holding unit) 6 that rotates the substrate W about a vertical rotation axis passing through the center portion of the substrate W while holding one substrate W within the chamber 5 in a horizontal position, a chemical liquid nozzle (processing liquid nozzle) 7 for supplying the chemical liquid to the substrate W held by the spin chuck 6, a cylindrical cup 8 that receives a processing liquid (a chemical liquid or a rinse liquid) exhausted from the substrate W and an induction heating unit 9 (see FIG. 2) that heats, by induction heating, a tip end portion 41a (first heating target part) of a nozzle pipe (processing liquid distribution pipe) of the chemical liquid nozzle 7.

As shown in FIG. 1, a first chemical liquid pipe (processing liquid pipe, processing liquid distribution pipe) 11 is connected to the chemical liquid nozzle 7. A chemical liquid supply pipe 13, which will be subsequently described, of the chemical liquid supply unit 3 is connected to the first chemical liquid pipe 11 via a chemical liquid valve 10. The chemical liquid supplied from the chemical liquid supply pipe 13 via the chemical liquid valve 10 and the first chemical liquid pipe 11 to the chemical liquid nozzle 7 is a chemical liquid whose processing ability is enhanced by increasing its temperature to a high temperature (temperature equal to or more than a room temperature). Examples of such a chemical liquid include sulfuric acid, SC1 (ammonia-hydrogen peroxide mixture) and SC2 (hydrochloric acid/hydrogen peroxide mixture). The chemical liquid that is adjusted to have a predetermined high temperature (for example, a constant temperature within a range of 40 to 80° C.) is supplied to the first chemical liquid pipe 11 from the chemical liquid supply unit 3.

The chemical liquid supply unit 3 includes a chemical liquid storage tank 12 that stores the chemical liquid, the chemical liquid supply pipe 13 that guides the chemical liquid within the chemical liquid storage tank 12 to the processing unit 2 (the chemical liquid nozzle 7), a liquid feed device 14 that moves the chemical liquid within the chemical liquid storage tank 12 to the chemical liquid supply pipe 13, a temperature adjustment unit 15 that makes contact with the chemical liquid passed within the chemical liquid supply pipe 13 and that heats the chemical liquid to adjust the temperature, a filter 16, a thermometer 17 that measures the temperature of the chemical liquid flowing within the chemical liquid supply pipe 13, the filter 16 that filters the chemical liquid flowing within the chemical liquid supply pipe 13, a return pipe 18 that connects the chemical liquid supply pipe 13 to the chemical liquid storage tank 12, a return valve 19 for opening and closing the return pipe 18 and a replenishing pipe 20 that replenishes the chemical liquid storage tank 12 with a new liquid of the chemical liquid. One end of the chemical liquid supply pipe 13 is connected to the first chemical liquid pipe 11, and the other end thereof is connected to the chemical liquid storage tank 12. The liquid feed device 14, the thermometer 17 and the filter 16 are interposed in this order along a chemical liquid distribution direction to the chemical liquid supply pipe 13. One end of the return pipe 18 is branch-connected to a first branch position 21 of the chemical liquid supply pipe 13, and the other end thereof is connected to the chemical liquid storage tank 12.

The chemical liquid storage tank 12, the upstream side portion of the chemical liquid supply pipe 13 with respect to the first branch position 21 and the return pipe 18 form a circulation path 22 that circulates the chemical liquid within the chemical liquid storage tank 12 while maintaining it at a high temperature (a predetermined high temperature higher than a room temperature). The circulation path 22 functions as a processing liquid holding unit that holds the chemical liquid while maintaining the chemical liquid (processing liquid) at a high temperature. The downstream side portion of the chemical liquid supply pipe 13 with respect to the first branch position 21 is assumed to be a second chemical liquid pipe 23. The processing liquid pipe includes the first chemical liquid pipe 11 and the second chemical liquid pipe 23.

The liquid feed device 14 may be a pump that sucks the liquid within the tank into the pipe or may be a pressure pipe that feeds the liquid within the tank into the pipe by supplying gas to increase the pressure within the tank. FIG. 1 shows an example where the liquid feed device 14 is a pump that is interposed in the chemical liquid supply pipe 13.

As shown in FIG. 1, in the state where the liquid feed device 14 is driven, the return valve 19 is opened with the chemical liquid valve 10 closed, and thus the chemical liquid pumped up from the chemical liquid storage tank 12 is fed back to the chemical liquid storage tank 12 through the thermometer 17, the filter 16 and the return pipe 18. In this way, the chemical liquid within the chemical liquid storage tank 12 is circulated in the circulation path 22.

In this state, the return valve 19 is closed and the chemical liquid valve 10 is opened, and thus the chemical liquid circulated in the circulation path 22 flows to the side of the second chemical liquid pipe 23, is supplied through the first chemical liquid pipe 11 to the chemical liquid nozzle 7 and is discharged from the chemical liquid nozzle 7. In this way, the chemical liquid is supplied to the substrate W to process the substrate W with the chemical liquid.

As shown in FIG. 2, the chamber 5 includes a box-shaped partition wall 25 where a carry-in and carry-out port 24 through which the substrate W is passed is provided and a shutter 26 which opens and closes the carry-in and carry-out port 24. The shutter 26 can be moved between an open position where the carry-in and carry-out port 24 is opened and a close position (position shown in FIG. 2) where the carry-in and carry-out port 24 is closed. A transfer robot (not shown) carries the substrate W into the chamber 5 through the carry-in and carry-out port 24 and carries the substrate W out of the chamber 5 through the carry-in and carry-out port 24.

As shown in FIG. 1, the spin chuck 6 includes a disc-shaped spin base 27 that is held in a horizontal position, a plurality of chuck pins 28 that hold the substrate W in the horizontal position above the spin base 27 and a spin motor 29 that rotates the chuck pins 28 to rotate the substrate W about the rotation axis A1. The spin chuck 6 is not limited to a clamping type chuck that brings a plurality of chuck pins 28 into contact with the circumferential end surface of the substrate W or may be a vacuum type chuck that sucks the rear surface (lower surface) of the substrate W which is a non-processing target surface to the upper surface of the spin base 27 to hold the substrate W horizontally.

As shown in FIGS. 1 and 2, the cup 8 includes a cylindrical splash guard 30 that surrounds the spin chuck 6 about the rotation axis A1 and a cylindrical wall 31 that surrounds the splash guard 30 about the rotation axis A1. The processing unit 2 includes a guard lifting/lowering unit 32 that vertically lifts and lowers the splash guard 30 between an upper position (position shown in FIG. 1) in which the upper end of the splash guard 30 is located higher than a position where the substrate W is held by the spin chuck 6 and a lower position in which the upper end of the splash guard 30 is located lower than the position where the substrate W is held by the spin chuck 6.

As shown in FIG. 2, in a plan view, the processing unit 2 includes a standby pot 39 (pot) that is arranged around the cup 8. The standby pot 39 is a pot for reception of the chemical liquid discharged from the chemical liquid nozzle 7 which is retracted from the upper surface of the substrate W.

As shown in FIG. 1, the processing unit 2 includes a rinse liquid nozzle 33 that discharges a rinse liquid toward the upper surface of the substrate W held by the spin chuck 6. The rinse liquid nozzle 33 is connected to a rinse liquid pipe 35 in which a rinse liquid valve 34 is interposed. The processing unit 2 may include a nozzle movement unit that moves the rinse liquid nozzle 33 between a processing position and an upper retraction position.

When the rinse liquid valve 34 is opened, the rinse liquid is supplied from the rinse liquid pipe 35 to the rinse liquid nozzle 33, and the rinse liquid is discharged from the rinse liquid nozzle 33. The rinse liquid is, for example, pure water (deionized water). The rinse liquid is not limited to pure water, and may be anyone of carbonated water, electrolytic ion water, hydrogen water, ozone water and dilute concentration (for example, about 10 to 100 ppm) hydrochloric acid water.

As shown in FIG. 1, the chemical liquid nozzle 7 is a nozzle that discharges the chemical liquid downward. The processing unit 2 includes a nozzle arm 36 that holds the chemical liquid nozzle 7 from above, an arm swing unit 37 that swings the nozzle arm 36 about a nozzle rotation axis A2 which is vertically extended about the cup 8 and an arm lifting/lowering unit 38 that lifts and lowers the nozzle arm 36.

The arm swing unit 37 swings the nozzle arm 36 to move the chemical liquid nozzle 7 along an arc-shaped path that passes through the substrate W in a plan view. In this way, as shown in FIG. 2, between the processing position P1 and the upper retraction position P2 apart from the processing position P1 in the horizontal direction, the chemical liquid nozzle 7 is moved horizontally.

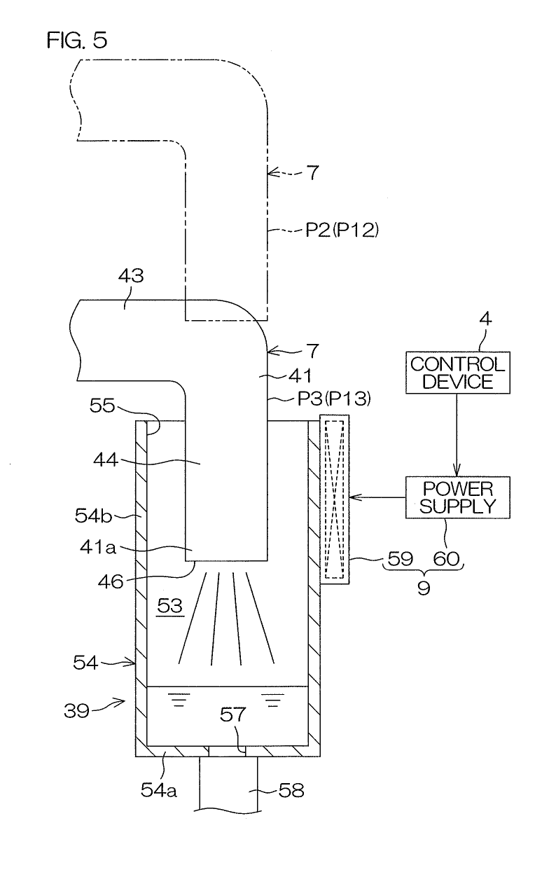

The arm lifting/lowering unit 38 lifts and lowers the nozzle arm 36 to move the chemical liquid nozzle 7 between the upper retraction position P2 (see FIG. 5 in addition to FIG. 2) set above the standby pot 39 and a lower retraction position P3 (retraction position, see FIG. 5 in addition to FIG. 2) set below the upper retraction position P2. In the state where the chemical liquid nozzle 7 is arranged in the lower retraction position P3, a hanging portion 44 of the chemical liquid nozzle 7 is accommodated within the standby pot 39. When the chemical liquid is not supplied from the chemical liquid nozzle 7 to the substrate W, the control device 4 controls the arm swing unit 37 and the arm lifting/lowering unit 38 to place the chemical liquid nozzle 7 on standby in the lower retraction position P3.

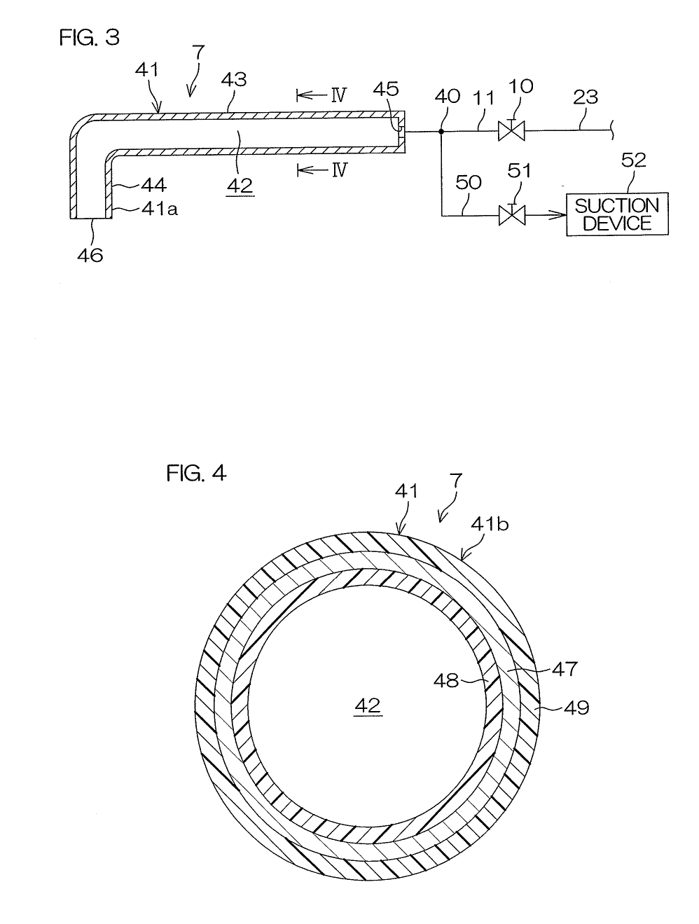

FIG. 3 is a cross-sectional view mainly showing the configuration of the chemical liquid nozzle 7. The chemical liquid nozzle 7 includes a cylindrical nozzle pipe 41. Within the nozzle pipe 41, a chemical liquid flow path (processing liquid flow path) 42 is defined. The nozzle pipe 41 includes a cylindrical horizontal portion 43 that is extended in the horizontal direction and the cylindrical hanging portion 44 that is vertically hung from a tip end portion of the horizontal portion 43. The chemical liquid flow path 42 is opened as a chemical liquid introduction port 45 in a base end portion of the horizontal portion 43, and is opened in a lower end portion (tip end portion) of the hanging portion 44 to form a circular discharge port 46. The downstream end of the first chemical liquid pipe 11 is connected to the chemical liquid introduction port 45. The chemical liquid introduced via the chemical liquid introduction port 45 from the first chemical liquid pipe 11 to the chemical liquid flow path 42 is passed along the chemical liquid flow path 42 and is discharged downward from the discharge port 46.

FIG. 4 is a diagram taken along cross-sectional line IV-IV of FIG. 3. The pipe wall 41b of the nozzle pipe 41 is formed in the shape of a concentric three-layer pipe. The pipe wall 41b includes a magnetic inductive member layer (first layer) 47, an inside protective layer 48 that is arranged on a inner circumference of the magnetic inductive member layer 47 and an outside protective layer (second layer) 49 that is arranged on an outer circumference of the magnetic inductive member layer 47. As an example of the magnetic inductive member layer 47, a SUS (Stainless Used Steel) layer can be illustrated. The inside protective layer 48 is formed of a resin material having a chemical resistance, and as an example of the resin material, PFA (perfluoroalkoxy ethylene) is used. The outside protective layer 49 is formed of a resin material having a chemical resistance, and as an example of the resin material, PTFE (polytetrafluoroethylene) is used.

Since the inside protective layer 48 and the outside protective layer 49 protect the magnetic inductive member layer 47, it is possible to increase the life of the magnetic inductive member layer 47. As will be described later, the magnetic inductive member layer 47 is inductively heated by the induction heating unit 9, and the induction heating of the magnetic inductive member layer 47 described above can be performed over a long period of time.

Since the magnetic inductive member layer 47 includes SUS, the pipe wall 41b of the nozzle pipe 41 can be satisfactorily increased in temperature by the induction heating from the induction heating unit 9. Moreover, since a SUS that has high strength is used as the material of the pipe wall 41b of the nozzle pipe 41, the shape of the nozzle pipe 41 can be maintained so as to have high rigidity.

As shown in FIGS. 1 and 3, a suction pipe 50 is branch-connected to a second branch position 40 set in a middle portion (that is, the downstream side with respect to the chemical liquid valve 10) of the first chemical liquid pipe 11. In a middle portion of the suction pipe 50, a suction valve 51 for opening and closing the suction pipe 50 is interposed. A suction device 52 is connected to the tip end of the suction pipe 50. The suction device 52 is, for example, constantly in an operated state. When in the operated state of the suction device 52, the suction valve 51 is opened, the function of the suction device 52 is activated, and thus the chemical liquid contained in the downstream side portion of the first chemical liquid pipe 11 with respect to the second branch position 40 and the chemical liquid contained within the nozzle pipe 41 of the chemical liquid nozzle 7 are sucked into the suction pipe 50. In this way, after the completion of the discharge of the chemical liquid from the chemical liquid nozzle 7, the suction valve 51 is opened, and thus the tip end surface of the chemical liquid can be significantly retracted from the discharge port 46 of the chemical liquid nozzle 7.

FIG. 5 is a cross-sectional view showing a schematic configuration of the standby pot 39. In FIG. 5, a state where the chemical liquid nozzle 7 is located in the lower retraction position P3 is indicated by solid lines, and a state where the chemical liquid nozzle 7 is located in the upper retraction position P2 is indicated by two-dot chain lines.

The standby pot 39 includes a housing 54 in the shape of, for example, a rectangular parallelepiped that partitions an internal space 53. In the housing 54, an insertion port 55 formed in the upper surface of the housing 54 and an exhaust port 57 formed in a lower wall 54a of the housing 54 are formed. One end of an exhaust pipe 58 is connected to the exhaust port 57 of the standby pot 39. The other end of the exhaust pipe 58 is connected to a waste liquid processing facility outside the apparatus.

The induction heating unit 9 includes an inductive coil 59 that is used for performing heating with an induction heating method and that is formed in the shape of, for example, a plate and a power supply unit 60 that supplies high-frequency power to the inductive coil 59. The inductive coil 59 is attached to a side wall 54b of the housing 54 from outside. The inductive coil 59 is arranged in a region of the side wall 54b that is opposite to the hanging portion 44 of the chemical liquid nozzle 7 located in the lower retraction position P3 in the horizontal direction and that is close thereto.

Although FIG. 1 shows that the upper surface of the housing 54 is opened, when the housing 54 has an upper wall, the insertion port 55 may be formed in the upper wall. In this case, the insertion port 55 is circular, and the diameter of the insertion port 55 is larger than that of the lower end portion of the chemical liquid nozzle 7.

The control device 4 controls the power supply unit 60 to supply high-frequency power having a predetermined magnitude to the inductive coil 59. When in the state where the chemical liquid nozzle 7 is located in the lower retraction position P3, the control device 4 controls the induction heating unit 9 to supply the high-frequency power to the inductive coil 59, the magnetic inductive member layer 47 (see FIG. 4) of the hanging portion 44 (the nozzle pipe 41) of the chemical liquid nozzle 7 generates heat to inductively heat the hanging portion 44. As shown in FIG. 5, the inductive coil 59 may be provided in such an area that the entire region of the hanging portion 44 of the chemical liquid nozzle 7 located in the lower retraction position P3 in an up/down direction is heated.

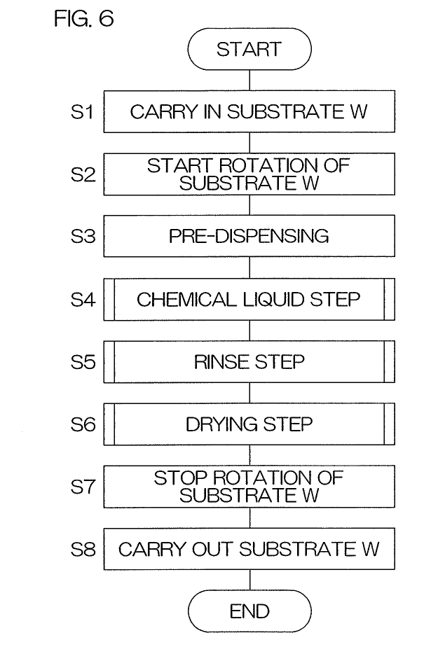

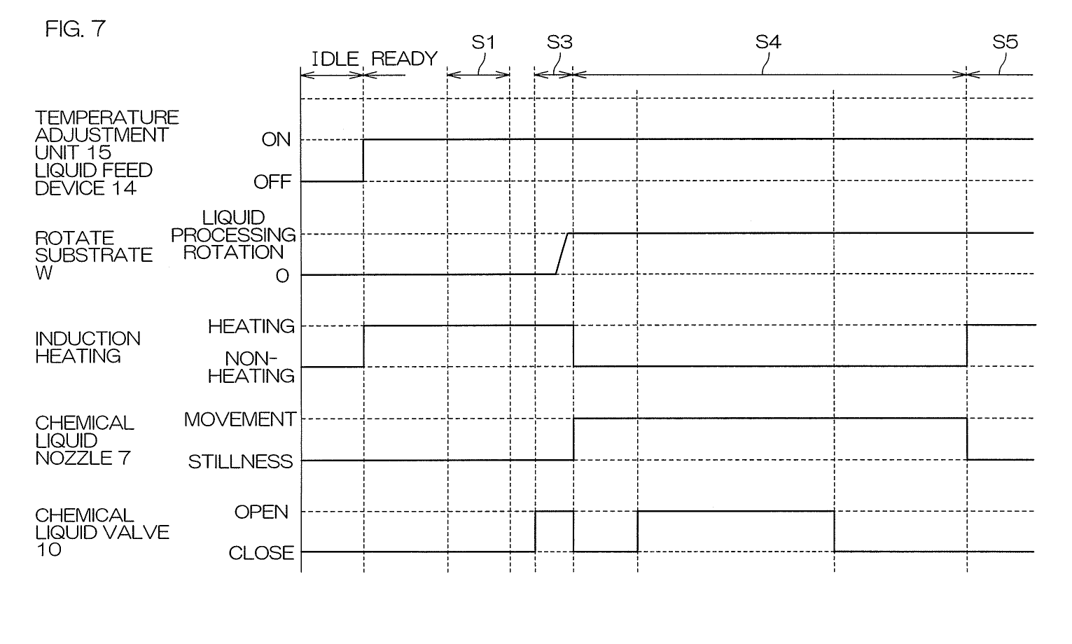

FIG. 6 is a flowchart for illustrating a processing example of processing performed by the substrate processing apparatus 1. FIG. 7 is a time chart for illustrating the details of the control performed by the control device 4 in the processing example.

The processing example will be described with reference to FIGS. 1 to 7. In the processing example, the chemical liquid is used, and thus washing processing or etching processing are performed on the upper surface of the substrate W.

Immediately after the startup of the substrate processing apparatus 1 (that is, the chemical liquid supply unit 3), the control device 4 starts the operation of the liquid feed device 14 and starts the operation of the temperature adjustment unit 15.

In this case, in the state where the liquid feed device 14 is operated, the control device 4 closes the chemical liquid valve 10 and opens the return valve 19. Hence, the chemical liquid pumped up from the chemical liquid storage tank 12 is circulated within the circulation path 22. In this way, the chemical liquid is heated by the temperature adjustment unit 15 such that its temperature is increased. The control device 4 constantly checks the output value of the thermometer 17 to monitor the temperature of the chemical liquid circulated within the circulation path 22. The chemical liquid of the circulation path 22 is increased in temperature in order to reach a predetermined processing temperature (for example, a predetermined temperature within a range of 40 to 80° C.), and after the chemical liquid reaches the processing temperature, the temperature of the chemical liquid is maintained at the processing temperature.

After the startup of the substrate processing apparatus 1 (that is, the processing unit 2), the chemical liquid nozzle 7 of the processing unit 2 is located in the lower retraction position P3. Immediately after the startup of the substrate processing apparatus 1, the control device 4 controls the power supply unit 60 to start the supply of the high-frequency power to the inductive coil 59. In this way, the magnetic inductive member layer 47 of the hanging portion 44 of the chemical liquid nozzle 7 generates heat to inductively heat the hanging portion 44. The control device 4 controls the power supply unit 60 to adjust the magnitude of the high-frequency power supplied to the inductive coil 59 such that the temperature of the hanging portion 44 of the chemical liquid nozzle 7 is equivalent to the temperature of the high-temperature chemical liquid supplied from the chemical liquid supply unit 3. In this way, the temperature of the hanging portion 44 is increased to the temperature equivalent to the temperature of the high-temperature chemical liquid supplied from the chemical liquid supply unit 3, and its temperature is maintained.

Immediately after the startup of the substrate processing apparatus 1, the control device 4 also starts the operation of the suction device 52.

When the substrate W is processed by the processing unit 2, in the state where the splash guard 30 is located in the lower position, the control device 4 carries the substrate W into the chamber 5 by the hand of the transfer robot (not shown) (step S1). The hand of the transfer robot is inserted and removed into and out of the chamber 5 through the carry-in and carry-out port 24 which is opened by the opening of the shutter 26. Then, in the state where the processing target surface (for example, a pattern formation surface) of the substrate W is directed upward, the control device 4 makes the transfer robot place the substrate W on the spin chuck 6. Thereafter, the control device 4 retracts the hand of the transfer robot from the interior of the chamber 5, and the carry-in and carry-out port 24 of the chamber 5 closes the shutter 26.

After the substrate W is placed on the chuck pins 28, the control device 4 presses the chuck pins 28 onto the circumferential edge portion of the substrate W, and thus the substrate W is held by the chuck pins 28. The control device 4 controls the guard lifting/lowering unit 32 to move the splash guard 30 from the lower position to the upper position. In this way, the upper end of the splash guard 30 is located higher than the substrate W.

Thereafter, the control device 4 controls the spin motor 29 to start the rotation of the substrate W. In this way, the rotation of the substrate W is started (step S2). Then, the substrate W is rotated at a predetermined liquid processing speed (for example, a few hundred rpm).

Next, although a chemical liquid step (step S4) of supplying the chemical liquid to the substrate W is performed, when the chemical liquid is not discharged from the chemical liquid nozzle 7 for a long period of time, pre-dispensing (step S3) is performed before the performance of the chemical liquid step (step S3).

In the pre-dispensing (S3), the chemical liquid is discharged from the chemical liquid nozzle 7 located in the lower retraction position P3 toward the standby pot 39. The pre-dispensing (S3) is performed due to the following reason. Specifically, when the chemical liquid is not discharged from the chemical liquid nozzle 7 for a long period of time, the pipe wall of the nozzle pipe 41 of the chemical liquid nozzle 7, the pipe walls of the first and second chemical liquid pipes 11 and 23 and the like may be lowered in temperature. Hence, the chemical liquid from the circulation path 22 which is adjusted to have the predetermined high temperature is passed along the second chemical liquid pipe 23, the first chemical liquid pipe 11 and the nozzle pipe 41. Consequently, the pipe walls of the first and second chemical liquid pipes 11 and 23 and the pipe wall of the nozzle pipe 41 are warmed by the chemical liquid of high temperature, and the temperature of these pipe walls is increased to a high temperature that is substantially equal to the temperature of the chemical liquid fed from the circulation path 22. In this way, thereafter, the chemical liquid is prevented from being cooled by the pipe walls of the first and second chemical liquid pipes 11 and 23 and the pipe wall of the nozzle pipe 41. Thus, it is possible to discharge, from the chemical liquid nozzle 7, the chemical liquid which is adjusted to have the desired high temperature from the beginning of the chemical liquid processing which is performed thereafter.

When the predetermined timing of the pre-dispensing is reached, in the state where the discharge port 46 of the chemical liquid nozzle 7 is directed to the lower wall 54a of the standby pot 39, the control device 4 closes the return valve 19 and opens the chemical liquid valve 10. In this way, the chemical liquid from the circulation path 22 which is adjusted to have the predetermined high temperature is passed within the second chemical liquid pipe 23, the first chemical liquid pipe 11 and the nozzle pipe 41 to warm the pipe wall of the second chemical liquid pipe 23, the pipe wall of the first chemical liquid pipe 11 and the pipe wall 41b of the nozzle pipe 41 and is discharged from the discharge port 46 of the chemical liquid nozzle 7. The chemical liquid discharged from the chemical liquid nozzle 7 toward the lower wall 54a of the standby pot 39 is received by the lower wall 54a of the standby pot 39, and is then guided through the exhaust pipe 58 to the waste liquid facility. When a predetermined pre-dispensing period has elapsed since the opening of the chemical liquid valve 10, the chemical liquid valve 10 is closed. The return valve 19 is opened.

As described above, the temperature of the pipe wall 41b of the nozzle pipe 41 of the hanging portion 44 is maintained at the temperature equivalent to the temperature of the high-temperature chemical liquid supplied from the chemical liquid supply unit 3. In other words, at the start of the pre-dispensing (S3), the hanging portion 44 has the temperature equivalent to the temperature of the high-temperature chemical liquid supplied from the chemical liquid supply unit 3. In this case, since only by pre-dispensing a small amount of chemical liquid, the temperature of the pipe wall of the second chemical liquid pipe 23, the pipe wall of the first chemical liquid pipe 11 and the pipe wall 41b of the nozzle pipe 41 can be increased to the temperature that is substantially equal to the temperature of the chemical liquid from the circulation path 22, the pre-dispensing period is set relatively short. Since the pre-dispensing period is short, a small amount of chemical liquid is consumed for the pre-dispensing.

After the chemical liquid valve 10 is closed, the control device 4 opens the suction valve 51. Thus, the function of the suction device 52 is activated, and the processing liquid present in the downstream side portion of the first chemical liquid pipe 11 with respect to the second branch position 40 is sucked and removed. In this way, it is possible to significantly retract the tip end surface of the chemical liquid from the discharge port 46 of the chemical liquid nozzle 7. The suction valve 51 is opened only for a predetermined time, and is thereafter opened. In this way, the pre-dispensing (S3) is completed.

After the pre-dispensing (S3), the chemical liquid step (step S4) of supplying the chemical liquid to the substrate W is performed. Specifically, the control device 4 controls the arm lifting/lowering unit 38 to lift the chemical liquid nozzle 7 from the lower retraction position P3 to the upper retraction position P2. Then, the control device 4 controls the arm swing unit 37 to move the chemical liquid nozzle 7 from the upper retraction position P2 to the processing position P1. After the chemical liquid nozzle 7 is arranged in the processing position P1, the control device 4 closes the return valve 19 and opens the chemical liquid valve 10 to discharge, from the chemical liquid nozzle 7, the chemical liquid toward the upper surface of the substrate W being rotated. The chemical liquid discharged from the chemical liquid nozzle 7 is supplied to the upper surface of the substrate W, and thereafter flows outward along the upper surface of the substrate W by a centrifugal force. Furthermore, in the state where the substrate W is rotated, the control device 4 moves the supply position of the chemical liquid to the upper surface of the substrate W between the center portion and the circumferential edge portion. In this way, the supply position of the chemical liquid is passed through the entire region of the upper surface of the substrate W, the entire region of the upper surface of the substrate W is scanned and the entire region of the upper surface of the substrate W is uniformly processed. When a predetermined period has elapsed since the opening of the chemical liquid valve 10, the control device 4 closes the chemical liquid valve 10 to stop the discharge of the chemical liquid from the chemical liquid nozzle 7 and opens the return valve 19.

After the closing of the chemical liquid valve 10, the control device 4 opens the suction valve 51. Thus, the function of the suction device 52 is activated, and the chemical liquid present on the downstream side with respect to the second branch position 40 is sucked and removed. In this way, it is possible to significantly retract the tip end surface of the chemical liquid from the discharge port 46 of the chemical liquid nozzle 7. The suction valve 51 is opened only for a predetermined time, and is thereafter closed. After the completion of the suction processing, no chemical liquid is present within the downstream side portion of the first chemical liquid pipe 11 with respect to the second branch position 40 and within the nozzle pipe 41 of the chemical liquid nozzle 7.

After the completion of the suction, the control device 4 controls the arm swing unit 37 to move the chemical liquid nozzle 7 from the processing position P1 to the upper retraction position P2. The control device 4 controls the arm lifting/lowering unit 38 to lower the chemical liquid nozzle 7 from the upper retraction position P2 to the lower retraction position P3 and to arrange it in the lower retraction position P3. In this way, the chemical liquid step (S4) is completed.

After the completion of the chemical liquid step (S4), a rinse step (step S5) of supplying the rinse liquid to the substrate W is performed. Specifically, the control device 4 opens the rinse liquid valve 34 to start the discharge of the rinse liquid from the rinse liquid nozzle 33. The rinse liquid discharged from the rinse liquid nozzle 33 is supplied to the upper surface of the substrate W being rotated. The chemical liquid adhered to the upper surface of the substrate W is washed out by this rinse liquid. The rinse liquid supplied to the substrate W is scattered from the upper surface circumferential edge portion of the substrate W toward the side of the substrate W, is received by the splash guard 30 of the cup 8 and is thereafter subjected to liquid exhaust processing. When a predetermined time has elapsed since the opening of the rinse liquid valve 34, the control device 4 closes the rinse liquid valve 34 to stop the discharge of the rinse liquid from the rinse liquid nozzle 33.

Next, the control device 4 controls the spin motor 29 to exceed the rotation speed of the substrate W and accelerate to a drying speed (for example, a few thousand rpm). In this way, the rinse liquid adhered to the upper surface of the substrate W is moved away, and thus the substrate W is dried (S6: a drying step).

When the drying step (S6) is performed over a predetermined period, the control device 4 controls the spin motor 29 to stop the rotation of the spin chuck 6 (the rotation of the substrate W) (step S7).

After the stop of the rotation of the substrate W, the guard lifting/lowering unit moves the splash guard 30 from the upper position to the lower position. Furthermore, the holding of the substrate W by the chuck pins 28 is cancelled. Thereafter, as the substrate W is carried in, the control device 4 makes the transfer robot carry the processed substrate W out of the chamber 5 (step S8).

As described above, in the first preferred embodiment, the tip end portion 41a (the hanging portion 44) of the nozzle pipe 41 containing the magnetic inductive member layer 47 formed with the SUS layer is set as the first heating target part which is inductively heated by the induction heating unit 9. The tip end portion 41a of the nozzle pipe 41 is inductively heated by the induction heating unit 9, and thus it is possible to increase the temperature of the tip end portion 41a of the nozzle pipe 41. Hence, in the state where the chemical liquid is not discharged from the chemical liquid nozzle 7, the tip end portion 41a of the nozzle pipe 41 is heated, and thus the tip end portion 41a can be maintained at the temperature that is substantially equal to the temperature of the chemical liquid supplied from the circulation path 22.

In this case, without a large amount of chemical liquid being discharged from the chemical liquid nozzle 7, only by discharging a small amount of chemical liquid from the chemical liquid nozzle 7, the temperature of the pipe wall of the second chemical liquid pipe 23, the pipe wall of the first chemical liquid pipe 11 and the pipe wall 41b of the nozzle pipe 41 can be increased to the temperature that is substantially equal to the temperature of the chemical liquid from the circulation path 22. Thus, it is possible to reduce the time necessary for the pre-dispensing, and it is also possible to reduce the amount of processing liquid consumed for the pre-dispensing.

In this way, it is possible to discharge, from the discharge port 46 of the chemical liquid nozzle 7, the chemical liquid which is adjusted to have the desired high temperature while reducing the time necessary for the pre-dispensing and/or reducing the amount of chemical liquid consumed for the pre-dispensing.

In the state where the chemical liquid nozzle 7 is located in the lower retraction position P3, the chemical liquid nozzle 7 is constantly inductively heated by the induction heating unit 9. In most of the period during which the chemical liquid is not supplied to the substrate W, the chemical liquid nozzle 7 is located in the lower retraction position P3. By effectively utilizing the period during which the chemical liquid is not supplied to the substrate W, the nozzle pipe 41 can be warmed.

In the state where the chemical liquid nozzle 7 is located in the lower retraction position P3 in which the pre-dispensing of the chemical liquid is performed, the chemical liquid nozzle 7 is inductively heated by the induction heating unit 9, and thus it is possible to continue to warm the nozzle pipe 41 of the chemical liquid nozzle 7 until the start of the pre-dispensing. In this case, it is possible to further reduce the time necessary for the pre-dispensing.

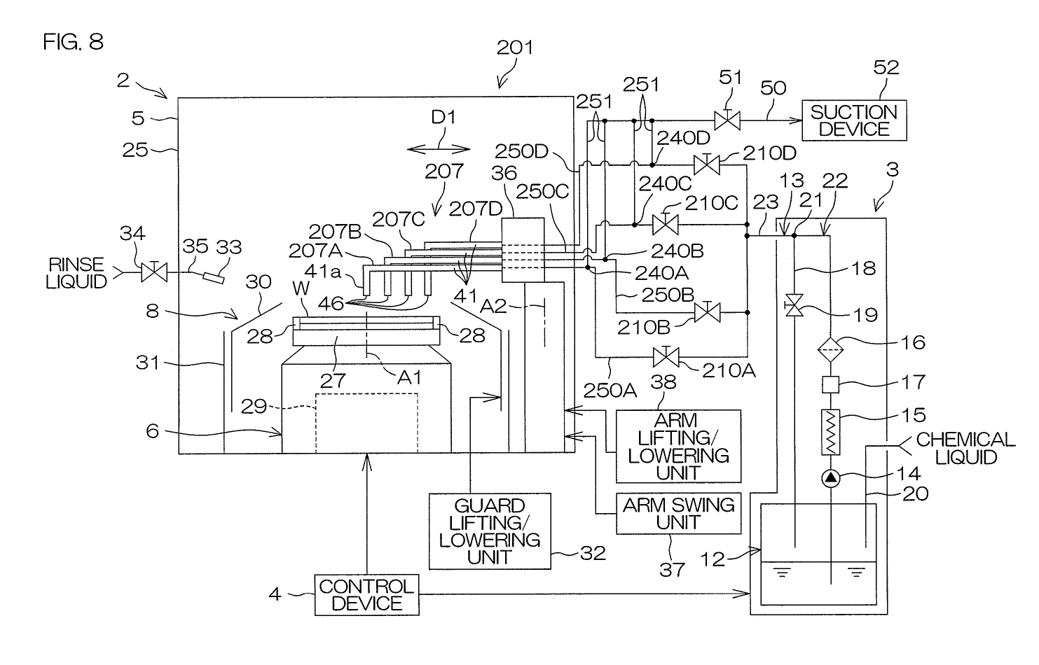

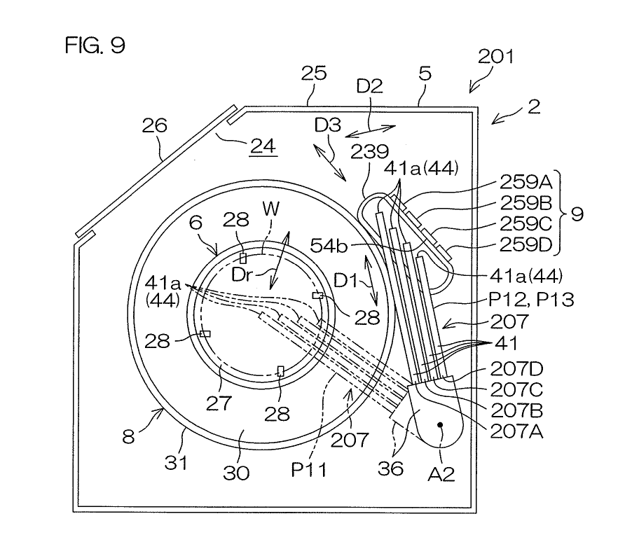

FIG. 8 is a diagram when a substrate processing apparatus 201 according to a second preferred embodiment of the present invention is seen in the horizontal direction. FIG. 9 is a schematic plan view showing the interior of the chamber 5 included in the substrate processing apparatus 201.

In the second preferred embodiment, portions corresponding to the individual portions described in the first preferred embodiment are identified with the same reference symbols as in the case of FIGS. 1 to 7, and the description thereof will be omitted.

The substrate processing apparatus 201 according to the second preferred embodiment differs from the substrate processing apparatus 1 according to the first preferred embodiment in that the nozzle arm 36 supports not one chemical liquid nozzle but a plurality of chemical liquid nozzles 207.

Each of the chemical liquid nozzles 207 includes the nozzle pipe 41 that is cantilevered by the nozzle arm 36. Since the configuration of this nozzle pipe is equivalent to that of the nozzle pipe 41 according to the first preferred embodiment, it is identified with the same reference symbol.

The chemical liquid nozzles 207 are aligned in the order of first to fourth nozzles 207A to 207D in a horizontal alignment direction D2 perpendicularly intersecting a horizontal longitudinal direction D1 which is the direction in which the nozzle pipe 41 is extended. Although in FIG. 8, the heights of a plurality of nozzle pipes 41 are different from each other, the nozzle pipes 41 are arranged at the same height. The interval between two nozzle pipes 41 adjacent in the alignment direction D2 may be the same as any of the other intervals or may be different from at least one of the other intervals. FIG. 9 shows an example where the nozzle pipes 41 are arranged at regular intervals.

The lengths of the nozzle pipes 41 in the longitudinal direction D1 are shortened in the order of the first to fourth nozzles 207A to 207D. The tip ends of the chemical liquid nozzles 207 (the tip ends of the nozzle pipes 41) are displaced in the longitudinal direction D1 so as to be aligned in the order of the first to fourth nozzles 207A to 207D in the longitudinal direction D1. The tip ends of the chemical liquid nozzles 207 are aligned in a straight line in a plan view.

The first to fourth nozzles 207A to 207D are respectively connected via first to fourth branch chemical liquid pipes 250A to 250D to the second chemical liquid pipe 23. In the first to fourth branch chemical liquid pipes 250A to 250D, first to fourth chemical liquid valves 210A to 210D are respectively interposed. When in the state where the return valve 19 is closed, the first chemical liquid valve 210A is opened, the chemical liquid circulated in the circulation path 22 flows to the side of the second chemical liquid pipe 23, is supplied through the first branch chemical liquid pipe 250A to the first nozzle 207A and is discharged from the first nozzle 207A. When in the state where the return valve 19 is closed, the second chemical liquid valve 210B is opened, the chemical liquid circulated in the circulation path 22 flows to the side of the second chemical liquid pipe 23, is supplied through the second branch chemical liquid pipe 250B to the second nozzle 207B and is discharged from the second nozzle 207B.

When in the state where the return valve 19 is closed, the third chemical liquid valve 210C is opened, the chemical liquid circulated in the circulation path 22 flows to the side of the second chemical liquid pipe 23, is supplied through the third branch chemical liquid pipe 250C to the third nozzle 207C and is discharged from the third nozzle 207C. When in the state where the return valve 19 is closed, the fourth chemical liquid valve 210D is opened, the chemical liquid circulated in the circulation path 22 flows to the side of the second chemical liquid pipe 23, is supplied through the fourth branch chemical liquid pipe 250D to the fourth nozzle 207D and is discharged from the fourth nozzle 207D.

The suction pipe 50 is branch-connected via a branch suction pipe 251 to branch positions 240A to 240D set in the downstream side portions of the branch chemical liquid pipes 250A to 250D with respect to the chemical liquid valves 210A to 210D. When the suction valve 51 is opened, the function of the suction device 52 is activated, and thus the chemical liquid contained in the downstream side portions of the branch chemical liquid pipes 250A to 250D with respect to the branch positions 240A to 240D and the chemical liquid contained within the nozzle pipes 41 of the nozzles 207A to 207D are sucked into the suction pipe 50. In this way, after the completion of the discharge of the chemical liquid from the chemical liquid nozzle 207, the suction valve 51 is opened, and thus the tip end surface of the chemical liquid can be significantly retracted from the discharge port 46 of each of the nozzles 207A to 207D.

The chemical liquid nozzle 207 is moved between a processing position and an upper retraction position P12 apart from the processing position in the horizontal direction by the swinging the arm 36 by the arm swing unit 37. The processing position is a position where the chemical liquid discharged from the chemical liquid nozzles 207 reaches the upper surface of the substrate W. In the processing position, the chemical liquid nozzles 207 and the substrate W are overlaid in a plan view, and the tip ends of the chemical liquid nozzles 207 are aligned, in a plan view, in a radial direction Dr from the side of the rotation axis A1 in the order of the first to fourth nozzles 207A to 207D. Here, the tip end of the first nozzle 207A is overlaid on the center portion of the substrate W in a plan view, and the tip end of the fourth nozzle 207D is overlaid on the circumferential edge portion of the substrate W in a plan view.

The arm lifting/lowering unit 38 lifts and lowers the nozzle arm 36 to move the chemical liquid nozzles 207 between an upper retraction position P12 (see FIG. 5 in addition to FIG. 9) set above a standby pot 239 and a lower retraction position P13 (retraction position, see FIG. 5 in addition to FIG. 9) set below the upper retraction position P12. In the state where the chemical liquid nozzles 207 are arranged in the lower retraction position P13, the chemical liquid nozzles 207 are accommodated within the standby pot 239 (see FIG. 9). When the chemical liquid is not supplied from the chemical liquid nozzle 7 to the substrate W, the control device 4 controls the arm swing unit 37 and the arm lifting/lowering unit 38 to place the chemical liquid nozzle 7 on standby in the lower retraction position P13.

Since the positional relationship in the up/down direction between the upper retraction position P12 and the lower retraction position P13 is equivalent to the positional relationship between the upper retraction position P2 (see FIG. 5) and the lower retraction position P3 (see FIG. 5) in the first preferred embodiment, the upper retraction position P12 and the lower retraction position P3 are shown in FIG. 5 so as to be enclosed in parentheses.

As shown in FIG. 9, the standby pot 239 is oval in a plan view, and has a length in a direction along an alignment direction D3 (horizontal direction perpendicularly intersecting a direction in which the tip ends of the nozzles 207A to 207D are aligned in the retraction positions P12 and P13). Except the above point, the standby pot 239 adopts the same configuration as the standby pot 39 according to the first preferred embodiment.

In the second preferred embodiment, instead of the inductive coil 59 according to the first preferred embodiment, a plurality of inductive coils (for example, plate-shaped coils, a first inductive coil 259A, a second inductive coil 259B, a third inductive coil 259C and a fourth inductive coil 259D) are used. The inductive coils 259A to 259D are attached to the side wall 54b of the housing 54 of the standby pot 239 from outside. The inductive coils 259A to 259D are aligned along the alignment direction D2.

The first inductive coil 259A is a coil for inductively heating the first nozzle 207A. The first inductive coil 259A is arranged in a region of the side wall 54b of the standby pot 239 that is opposite to the hanging portion 44 of the first nozzle 207A located in the lower retraction position P13 in the horizontal direction and that is close thereto.

The second inductive coil 259B is a coil for inductively heating the second nozzle 207B. The second inductive coil 259B is arranged in a region of the side wall 54b of the standby pot 239 that is opposite to the hanging portion 44 of the second nozzle 207B located in the lower retraction position P13 in the horizontal direction and that is close thereto.

The third inductive coil 259C is a coil for inductively heating the third nozzle 207C. The third inductive coil 259C is arranged in a region of the side wall 54b of the standby pot 239 that is opposite to the hanging portion 44 of the third nozzle 207C located in the lower retraction position P13 in the horizontal direction and that is close thereto.

The fourth inductive coil 259D is a coil for inductively heating the fourth nozzle 207D. The fourth inductive coil 259D is arranged in a region of the side wall 54b of the standby pot 239 that is opposite to the hanging portion 44 of the fourth nozzle 207D located in the lower retraction position P13 in the horizontal direction and that is close thereto.

High-frequency power is supplied from the power supply unit 60 (see FIG. 5) to the inductive coils 259A to 259D. When the high-frequency power is supplied to the inductive coils 259A to 259D, the magnetic inductive member layer 47 (see FIG. 4) of the hanging portion 44 (the nozzle pipe 41) of the corresponding nozzles 207A to 207D generates heat, and thus the hanging portion 44 is inductively heated. The inductive coils 259A to 259D may be provided in such an area that the substantially entire region of the hanging portion 44 of the corresponding nozzles 207A to 207D located in the lower retraction position P3 in the up/down direction is heated.

In the second preferred embodiment, the actions and effects equivalent to the actions and effects of the first preferred embodiment are achieved. In addition to the actions and effects of the first preferred embodiment, since the inductive coils 259A to 259D are respectively provided in the nozzles 207A to 207D, it is possible to efficiently heat the hanging portion 44 of the nozzle pipe 41 of each of the chemical liquid nozzles 207.

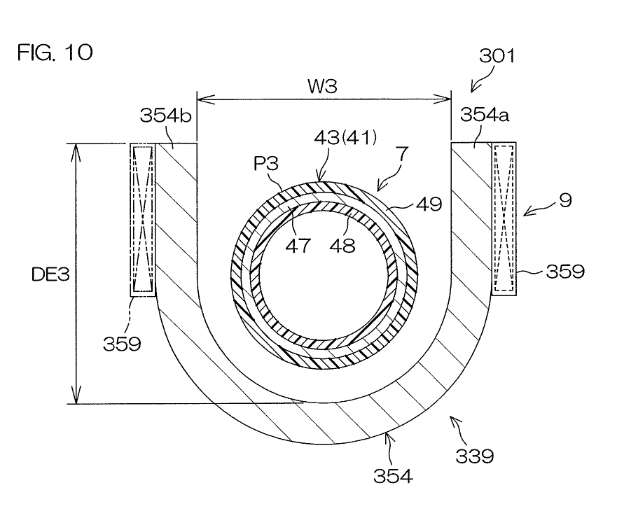

FIG. 10 is a cross-sectional view showing a state where a chemical liquid nozzle 7 according to a third preferred embodiment of the present invention is in the retraction position.

A substrate processing apparatus 301 according to the third preferred embodiment of the present invention differs from the substrate processing apparatus 1 according to the first preferred embodiment in that a standby gutter 339 is provided. The other portions have the configuration equivalent to the substrate processing apparatus 1 according to the first preferred embodiment.

The substrate processing apparatus 301 includes the gutter-shaped standby gutter 339 for accommodating the horizontal portion 43 of the nozzle pipe 41 of the chemical liquid nozzle 7 located in the lower retraction position (retraction position) P3. The standby gutter 339 forms a housing 354 that has a pipe shape whose cross-sectional view is formed substantially in the shape of the letter U. The longitudinal direction of the housing 354 is along the longitudinal direction of the horizontal portion 43 of the chemical liquid nozzle 7. In the inner circumference of the housing 354, an inner wall groove 340 is formed which accommodates the horizontal portion 43 of the nozzle pipe 41 therewithin and whose cross-sectional view is formed substantially in the shape of the letter U. The width W3 and the depth DE3 of the inner wall groove 340 are set such that the inner wall groove 340 can accommodate the horizontal portion 43 of the nozzle pipe 41.

On one (for example, a side wall 354a on the right side of FIG. 10) of a pair of side walls 354a and 354b of the housing 354 in the standby gutter 339, for example, a plate-shaped inductive coil 359 is arranged from outside. The inductive coil 359 is provided instead of the inductive coil 59 (see FIG. 5) according to the first preferred embodiment.

High-frequency power is supplied from the power supply unit 60 (see FIG. 5) to the inductive coil 359. When the high-frequency power is supplied to the inductive coil 359, the magnetic inductive member layer 47 of the horizontal portion (the nozzle pipe 41) of the chemical liquid nozzle 7 generates heat, and thus the hanging portion 44 is inductively heated.

The inductive coil 359 is arranged in a region that is opposite to the horizontal portion 43 of the chemical liquid nozzle 7 located in the lower retraction position P3 in the horizontal direction and that is close thereto. The inductive coil 359 may be provided so as to cover a substantially entire region of the standby gutter 339 in the longitudinal direction.

Although FIG. 10 shows the configuration in which the inductive coil 359 is provided only on one side wall 354a of the housing 354, as indicated by two-dot chain lines in FIG. 10, the inductive coil 359 may also be provided on the other side wall 354b.

When the third preferred embodiment is adopted, the inductive coils 359 may be provided both in the standby gutter 339 and the standby pot 39 or the inductive coil 359 may be provided only in the standby gutter 339.

In the third preferred embodiment, the actions and effects equivalent to the actions and effects of the first preferred embodiment are achieved. In addition to the actions and effects of the first preferred embodiment, the horizontal portion 43 (first heating target part) of the nozzle pipe 41 including the magnetic inductive member layer 47 formed with the SUS layer is inductively heated by the induction heating unit 9. In this way, not only the tip end portion 41a of the nozzle pipe 41 but also the entire nozzle pipe 41 can be increased in temperature. Hence, in the state where the chemical liquid is not discharged from the chemical liquid nozzle 7, the entire nozzle pipe 41 can be maintained at the temperature that is substantially equal to the temperature of the chemical liquid supplied from the circulation path 22.

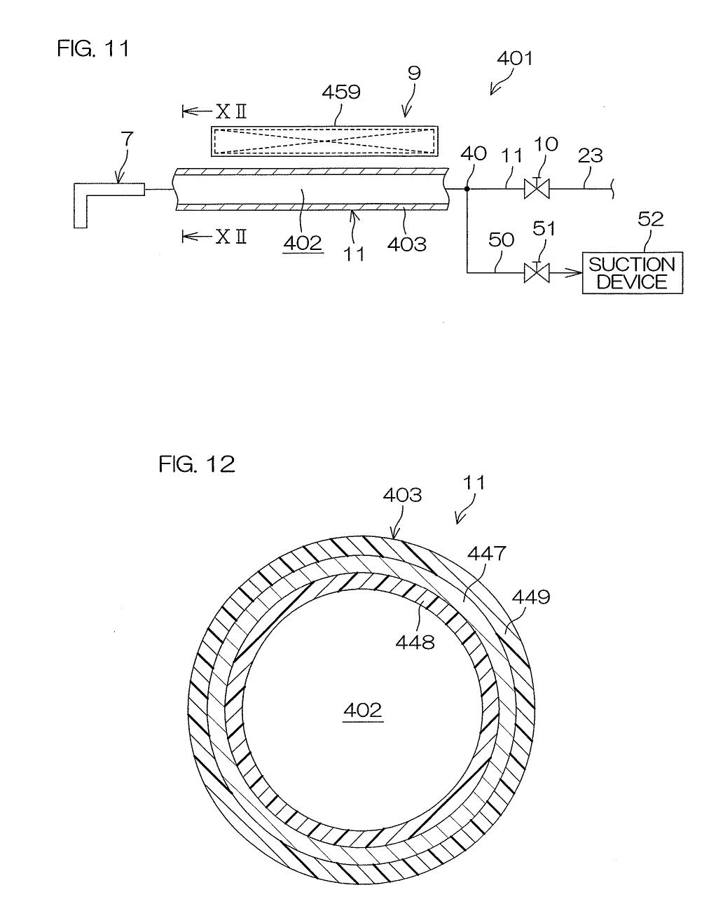

FIG. 11 is a cross-sectional view mainly showing the configuration of the vicinity of the first chemical liquid pipe 11 according to a fourth preferred embodiment of the present invention. FIG. 12 is a diagram taken along cross-sectional line XII-XII of FIG. 11.

In the fourth preferred embodiment, portions corresponding to the individual portions described in the first preferred embodiment are identified with the same reference symbols as in the case of FIGS. 1 to 7, and the description thereof will be omitted.

A substrate processing apparatus 401 according to the fourth preferred embodiment differs from the substrate processing apparatus 1 according to the first preferred embodiment in that the nozzle pipe 41 of the chemical liquid nozzle 7 is not heated but the pipe wall 403 (at least part thereof, second heating target part) of the first chemical liquid pipe 11 is heated. The other portions have the configuration equivalent to the substrate processing apparatus 1 according to the first preferred embodiment.

Within the first chemical liquid pipe 11, a chemical liquid flow path (processing liquid flow path) 402 is defined. The pipe wall 403 of the first chemical liquid pipe 11 is formed in the shape of a concentric three-layer pipe. The pipe wall 403 includes a magnetic inductive member layer (first layer) 447, an inside protective layer 448 that is arranged on the inner circumferential surface of the magnetic inductive member layer 447 and an outside protective layer (second layer) 449 that is arranged on the outer circumferential surface of the magnetic inductive member layer 447. As an example of the magnetic inductive member layer 447, a SUS (stainless) layer can be illustrated. Examples of the other material of the magnetic inductive member layer 447 can include Fe (iron), Co (cobalt), Ni (nickel) and Cr (chromium). The inside protective layer 448 is formed of a resin material having a chemical resistance, and as an example of the resin material, PFA (perfluoroalkoxy ethylene) is used. The outside protective layer 449 is formed of a resin material having a chemical resistance, and as an example of the resin material, PTFE (polytetrafluoroethylene) is used.

Since the inside protective layer 448 and the outside protective layer 449 protect the magnetic inductive member layer 447, it is possible to increase the life of the magnetic inductive member layer 447. As will be described later, the magnetic inductive member layer 447 is inductively heated by the induction heating unit 9, and the induction heating of the magnetic inductive member layer 447 described above can be performed over a long period of time.

Since the magnetic inductive member layer 447 includes SUS, the pipe wall 403 of the first chemical liquid pipe 11 can be satisfactorily increased in temperature by the induction heating from the induction heating unit 9. Moreover, since a SUS that has high strength is used as the material of the first chemical liquid pipe 11, the shape of the first chemical liquid pipe 11 can be maintained so as to have high rigidity.

As the induction heating unit 9, instead of the inductive coil 59 (see FIG. 5), for example, a plate-shaped inductive coil 459 is adopted. The inductive coil 459 is arranged close to and opposite to the heating target part (the second heating target part) of the first chemical liquid pipe 11. Although FIG. 11 shows the case where the inductive coil 459 is arranged above the first chemical liquid pipe 11, the inductive coil 459 may be arranged below or to the side of the first chemical liquid pipe 11 or the first chemical liquid pipe 11 may be sandwiched between a pair of the inductive coils 459.

As described above, in the fourth preferred embodiment, the first chemical liquid pipe 11 including the magnetic inductive member layer 447 formed with the SUS layer is set as the second heating target part which is inductively heated by the induction heating unit 9. The first chemical liquid pipe 11 is inductively heated by the induction heating unit 9, and thus it is possible to increase the temperature of the first chemical liquid pipe 11. Hence, in the state where the chemical liquid is not discharged from the chemical liquid nozzle 7, the first chemical liquid pipe 11 is heated, and thus the pipe wall 403 of the first chemical liquid pipe 11 can be maintained at the temperature that is substantially equal to the temperature of the chemical liquid supplied from the circulation path 22.

In this way, it is possible to discharge, from the discharge port 46 of the chemical liquid nozzle 7, the chemical liquid which is adjusted to have the desired high temperature while reducing the time necessary for the pre-dispensing and/or reducing the amount of chemical liquid consumed for the pre-dispensing.

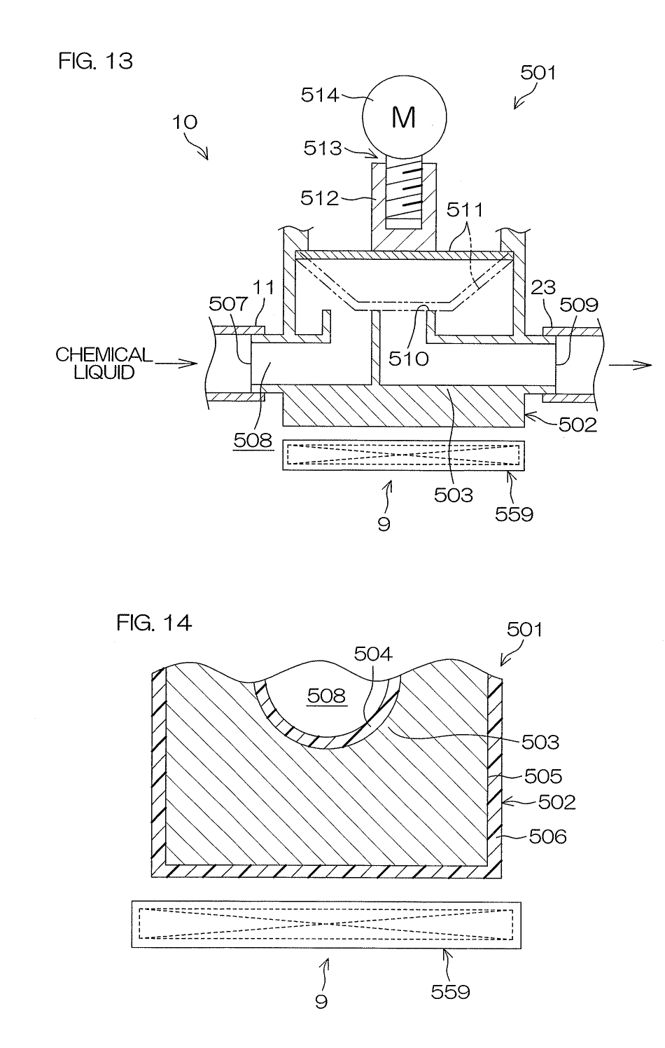

FIG. 13 is a schematic cross-sectional view showing the configuration of a chemical liquid valve 10 according to a fifth preferred embodiment of the present invention. FIG. 14 is an enlarged cross-sectional view showing a part of the configuration shown in FIG. 13.

A substrate processing apparatus 501 according to the fifth preferred embodiment of the present invention differs from the substrate processing apparatus 1 according to the first preferred embodiment in that the nozzle pipe 41 of the chemical liquid nozzle 7 is not heated but the valve body 502 of the chemical liquid valve 10 is heated. The other portions have the configuration equivalent to the substrate processing apparatus 1 according to the first preferred embodiment.

In FIG. 13, a valve member 511 in an opened state is indicated by solid lines, and the valve member 511 in a closed state is indicated by two-dot chain lines. The internal structure of the chemical liquid valve 10 will be described below with reference to FIG. 13.

The chemical liquid valve 10 is, for example, a diaphragm valve. The chemical liquid valve 10 includes a valve body (third heating target part) 502 in which a chemical liquid flow path (processing liquid flow path) 508 is formed. The valve body 502 includes an inlet port 507 into which the liquid flows, an outlet port 509 from which the liquid flowing into the inlet port 507 is discharged, a chemical liquid flow path 508 which connects the inlet port 507 and the outlet port 509, an annular valve seat 510 which surrounds the chemical liquid flow path 508 and the valve member 511 which is arranged within the chemical liquid flow path 508. The valve member 511 is a diaphragm that is formed of an elastic material such as rubber or resin. The second chemical liquid pipe 23 is connected to the inlet port 507, and the first chemical liquid pipe 11 is connected to the outlet port 509.

The chemical liquid valve 10 includes a valve actuator that opens and closes a valve main body. The valve actuator includes a rod 512 that is moved together with the valve member 511, an electric motor 514 that generates motive power which moves the rod 512 in the axial direction and a motion conversion mechanism 513 that converts the rotation of the electric motor 514 into a linear motion of the rod 512. When the electric motor 514 is rotated, the rod 512 is moved in the axial direction of the rod 512 by a movement amount corresponding to the rotation angle of the electric motor 514. The rod 512 can be moved in the axial direction of the rod 512 between an opened position (position shown in FIG. 13) where the valve member 511 is separated from the valve seat 510 and a closed position where the valve member 511 is pressed by the valve seat 510.

When the rod 512 is moved to the side of the closed position in the state where the valve member 511 is separate from the valve seat 510, part of the valve member 511 approaches the valve seat 510. When the rod 512 reaches the closed position, the valve member 511 makes contact with the valve seat 510, and thus the chemical liquid flow path 508 is closed. On the other hand, when the rod 512 is moved to the side of the opened position in the state where the valve member 511 is pressed onto the valve seat 510, the valve member 511 is separated from the valve seat 510, and thus the chemical liquid flow path 508 is opened.

As shown in FIG. 14, the valve body 502 is formed of a magnetic inductive member material such as SUS (stainless). As the material of the valve body 502, other magnetic inductive member materials such as Fe (iron), Co (cobalt), Ni (nickel) and Cr (chromium) may be used. On the inner wall portion (processing liquid distribution pipe) 503 of the valve body 502 that partitions the chemical liquid flow path 508, a resin coating 504 having a chemical resistance is arranged. On the outer portion 505 of the valve body 502, a resin coating 506 having a chemical resistance is also arranged. Examples of the resins having a chemical resistance that are used as the resin coatings 504 and 506 include PFA (perfluoroalkoxy ethylene) and PTFE (polytetrafluoroethylene).

The induction heating unit 9 adopts, for example, a plate-shaped inductive coil 559, instead of the inductive coil 59 (see FIG. 5). The inductive coil 559 is arranged in the heating target part (the third heating target part) of the valve body 502, in particular, in a position close to the inner wall portion 503. Although FIG. 11 shows the case where the inductive coil 559 is arranged above the valve body 502, the inductive coil 559 may be arranged below or to the side of the valve body 502 or the valve body 502 may be sandwiched between a pair of the inductive coils 559.

As described above, in the fifth preferred embodiment, the valve body 502 formed with the magnetic inductive member such as SUS is set as the third heating target part which is inductively heated by the induction heating unit 9. The valve body 502 is inductively heated by the induction heating unit 9, and thus it is possible to increase the temperature of the inner wall portion 503 of the valve body 502. Hence, in the state where the chemical liquid is not discharged from the chemical liquid nozzle 7, the valve body 502 is heated, and thus the inner wall portion 503 of the valve body 502 can be maintained at the temperature that is substantially equal to the temperature of the chemical liquid supplied from the circulation path 22.

In this way, it is possible to discharge, from the discharge port 46 of the chemical liquid nozzle 7, the chemical liquid which is adjusted to have the desired high temperature while reducing the time necessary for the pre-dispensing and/or reducing the amount of chemical liquid consumed for the pre-dispensing.

Although this invention is described above using the five preferred embodiments, this invention can be practiced with other preferred embodiments.

The configuration in which the heating target part (the nozzle pipe 41, the first chemical liquid pipe 11 and the valve body 502) includes SUS or the like as the magnetic inductive member is described using the example. However, as still other magnetic inductive members, metals such as A1 (aluminum) can be adopted.

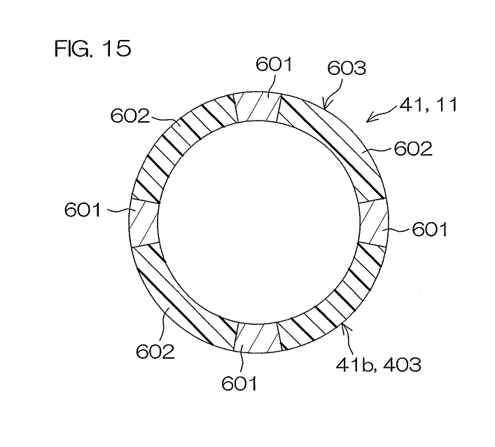

The magnetic inductive member included in the heating target part may be formed of, instead of metal, a carbon material GC (glassy carbon) or the like. As shown in FIG. 15, the pipe wall 41b of the nozzle pipe 41 and the pipe wall 403 of the first chemical liquid pipe 11 may be formed of a carbon fiber 601 and a composite material 603 including a chemical resistant resin 602. In this case, as an example of the chemical resistant resin, PFA can be taken.

In the first to fourth preferred embodiments, as the inside protective layers 48 and 448 of the pipe wall 41b of the nozzle pipe 41 or the pipe wall 403 of the first chemical liquid pipe 11, a resin (for example, PTFE) other than PFA may be adopted or as the outside protective layers 49 and 449 of the pipe wall 41b of the nozzle pipe 41 or the pipe wall 403 of the first chemical liquid pipe 11, a resin (for example, PFA) other than PTFE may be adopted.

Although in the above description, the pipe wall 41b of the nozzle pipe 41 or the pipe wall 403 of the first chemical liquid pipe 11 is formed in the shape of a three-layer pipe, as long as the pipe wall 41b of the nozzle pipe 41 or the pipe wall 403 of the first chemical liquid pipe 11 includes at least a magnetic inductive member layer (the magnetic inductive member layer 47, 447) and an outside protective layer (the outside protective layer 49, 449), any configuration may be adopted.

In the first and second preferred embodiments, the third preferred embodiment and the fourth preferred embodiment, the method is described of selectively heating any of the nozzle pipe 41, the first chemical liquid pipe 11 and the valve body 502 by induction heating. However, two or more (more preferably, all) of the nozzle pipe 41, the first chemical liquid pipe 11 and the valve body 502 may be simultaneously heated by induction heating.

Although in the first and second preferred embodiments, the inductive coil 59, 259 is attached to the member (the standby pot 39) which is not rotated together with the chemical liquid nozzle 7, 207, a member (for example, the nozzle arm 36) which can be rotated together with the chemical liquid nozzle 7, 207 may be made to support the inductive coil.

Although in each of the preferred embodiments, the configuration in which the heating target part is heated by the induction heating method is described as an example, instead of the induction heating method, a direct heating method of directly applying current to the heating target part to heat the portion or an indirect heating method of supplying a high-temperature fluid or a high-temperature liquid to the heating target part to heat the portion may be adopted.

Although in the description of each of the preferred embodiments, the pre-dispensing is used, the pre-dispensing may be eliminated.

The second preferred embodiment may be combined with the third to fifth preferred embodiments. Specifically, in the substrate processing apparatus in which a plurality of chemical liquid nozzles 207 are supported by the nozzle arm 36, the horizontal portion 43 of the first to fourth nozzles 207A to 207D may be inductively heated, the first to fourth branch chemical liquid pipes 250A to 250D may be inductively heated or the chemical liquid valve 10 may be inductively heated.

Although as the processing liquid distribution pipe to be heated by induction heating, the pipe along which the chemical liquid is passed is described as an example, a pipe along which water such as the rinse liquid is passed can be adopted as the processing liquid distribution pipe. Although in the preferred embodiments discussed above, the case where the substrate processing apparatus 1, 201, 301, 401, 501 is the system which processes the disc-shaped substrate W is described, the substrate processing apparatus 1, 201, 301, 401, 501 may be a system which processes a polygonal substrate such as a liquid crystal display device glass substrate.

Although in the preferred embodiments described above, as the substrate to be processed, the substrate W is used, there is no limitation to the substrate W, for example, other types of substrates such as substrates for liquid crystal display devices, substrates for plasma displays, substrates for FEDs, substrates for optical discs, substrates for magnetic discs, substrates for optical magnetic discs, substrates for photomasks, ceramic substrates and substrates for solar cells may be targets to be processed.

Various design modifications can be performed in the range described in the scope of claims.

Although the preferred embodiments of the present invention are described in detail, they are simply specific examples that are used so as to clarify the technical details of the present invention, the present invention should not be interpreted by being limited to these specific examples and the scope of the present invention is limited only by the scope of claims attached.

This application corresponds to Japanese Patent Application No. 2015-47569 filed with Japan Patent Office on Mar. 10, 2015, and the entire disclosure of this application is incorporated herein by reference.

What is claimed is:

1. A substrate processing apparatus comprising:
a substrate holding unit that holds a substrate,
a processing liquid nozzle that includes a nozzle pipe within which a processing liquid flow path for passing a processing liquid is defined and a discharge port to which the processing liquid flow path is opened,
a processing liquid holding unit that holds the processing liquid while maintaining the processing liquid at a predetermined high temperature higher than a room temperature,
a processing liquid pipe that is connected to the processing liquid holding unit and the processing liquid nozzle and that guides the processing liquid held by the processing liquid holding unit to the processing liquid nozzle, and
an induction heating unit that heats, by induction heating, a heating target part which is provided in at least a part of a processing liquid distribution pipe including the processing liquid pipe and the nozzle pipe and which contains a magnetic inductive member material and/or a carbon material.

2. The substrate processing apparatus according to claim 1,
wherein the heating target part includes a first heating target part which is provided in at least a part of the nozzle pipe of the processing liquid nozzle.

3. The substrate processing apparatus according to claim 2,
wherein the processing liquid nozzle is provided such that the processing liquid nozzle can be moved between a processing position where the processing liquid is supplied to the substrate held by the substrate holding unit and a retraction position where the processing liquid nozzle is retracted from the substrate holding unit, and
the induction heating unit heats the first heating target part of the processing liquid nozzle which is located in the retraction position.

4. The substrate processing apparatus according to claim 2, further comprising:
a chamber that accommodates the substrate holding unit and the processing liquid nozzle,
wherein the chamber accommodates a plurality of the processing liquid nozzles,
each of the processing liquid nozzles includes the first heating target part and
the induction heating unit heats each of the first heating target parts.

5. The substrate processing apparatus according to claim 1,
wherein the heating target part includes a second heating target part that is provided in at least a part of the processing liquid pipe.

6. The substrate processing apparatus according to claim 1,
wherein the heating target part includes a third heating target part that is provided in at least a part of a valve body of a valve interposed in the processing liquid pipe.

7. The substrate processing apparatus according to claim 1,
wherein the processing liquid distribution pipe has a multilayer structure that includes a first layer which includes the magnetic inductive member material and/or the carbon material and a second layer which surrounds a circumference of the first layer and which protects the first layer.

8. The substrate processing apparatus according to claim 1,
wherein the magnetic inductive member material includes SUS.

9. The substrate processing apparatus according to claim 1,
wherein the induction heating unit includes an inductive coil and a power supply unit that supplies high-frequency power to the inductive coil.

10. The substrate processing apparatus according to claim 9,
wherein the heating target part includes a first heating target part which is provided in at least a part of the nozzle pipe,
the processing liquid nozzle is provided such that the processing liquid nozzle can be moved between a processing position where the processing liquid is supplied to the substrate held by the substrate holding unit and a retraction position where the processing liquid nozzle is retracted from the substrate holding unit and
the inductive coil is provided such that the inductive coil can heat the first heating target part of the processing liquid nozzle which is located in the retraction position.

11. The substrate processing apparatus according to claim 10,
wherein in the retraction position, a pot is provided that receives the processing liquid discharged from the processing liquid nozzle, and the inductive coil is arranged on a wall of the pot.

12. A substrate processing method of supplying a processing liquid having a predetermined high temperature higher than a room temperature to a processing liquid nozzle that includes a nozzle pipe within which a processing liquid flow path for passing the processing liquid is defined and a discharge port to which the processing liquid flow path is opened via a processing liquid pipe so as to process the substrate with the processing liquid discharged from the processing liquid nozzle, the substrate processing method comprising:
a heating step of heating a heating target part provided in at least a part of a processing liquid distribution pipe including the processing liquid pipe and the nozzle pipe in a state where the processing liquid is not present within the heating target part so as to maintain a temperature of the heating target part at a high temperature which is higher than the room temperature but lower than a boiling point of the processing liquid.

13. The substrate processing method according to claim 12,
wherein the heating target part contains a magnetic inductive member material and/or a carbon material, and
the heating step includes an induction heating step of heating the heating target part by induction heating.

14. The substrate processing method according to claim 12, further comprising:
a nozzle movement step of moving the processing liquid nozzle between a processing position where the discharge port is opposite to a main surface of the substrate and a retraction position where the discharge port is retracted from the main surface of the substrate,
wherein in the heating step, while the processing liquid nozzle is located in the retraction position, the heating target part is heated.

15. The substrate processing method according to claim 12,
wherein the heating step includes a first heating step of heating a first heating target part provided in at least a part of the nozzle pipe.
